(19) United States
(12) Patent Application Publication
(10) Pub. No.: US 2013/0270535 A1
(43) Pub. Date: Oct. 17, 2013

(54) POLYMER AND ORGANIC LIGHT-EMITTING DEVICE

(71) Applicants: Jonathan Pillow, Stotfold (GB); Martin Humphries, Cambridgeshire (GB); Simon King, Cambridgeshire (GB)

(72) Inventors: Jonathan Pillow, Stotfold (GB); Martin Humphries, Cambridgeshire (GB); Simon King, Cambridgeshire (GB)

(73) Assignees: SUMITOMO CHEMICAL COMPANY LIMITED, Tokyo (JP); CAMBRIDGE DISPLAY TECHNOLOGY LIMITED, Cambridgeshire (GB)

(21) Appl. No.: 13/880,234

(22) PCT Filed: Oct. 18, 2011
(86) PCT No.: PCT/GB11/01488

§ 371 Date: Jul. 3, 2013

(30) Foreign Application Priority Data
Oct. 19, 2010 (GB) 1017626.1
Oct. 19, 2010 (GB) 1017628.7

(51) Int. Cl. H01L 51/50; H01L 51/56

(52) U.S. Cl. CPC H01L 51/5016; H01L 51/56
USPC 257/40; 438/46; 528/8

(57) ABSTRACT

An organic light-emitting device comprises an anode, a cathode, a light-emitting layer between the anode and the cathode and a hole transporting layer between the anode and the light-emitting layer. The hole transporting layer comprises a hole-transporting material having a triplet energy level, and a triplet-quenching unit having a triplet energy level that is lower than the triplet energy level of the hole-transporting material. The triplet quenching unit is selected from the group consisting of polyaromatic hydrocarbons such as 2,6-anthracenes, 9,10-anthracenes and derivatives thereof; anthanthrenes and derivatives thereof; distyryl aryls and derivatives thereof such as distyrylbenzenes, distyrylbiphenyls, stilbenes, fulvenes, dibenzofulvenes, perylenes, linear polyenes (from 2 to 6 alkenes) and cyclic polyenes, each of which may optionally be substituted with one or more substituents.

### FIELD OF THE INVENTION

The present invention relates to polymers, in particular hole-transporting polymers, suitable for use in organic light-emitting devices, and organic light-emitting devices comprising the same.

### BACKGROUND OF THE INVENTION

Electronic devices comprising active organic materials are attracting increasing attention for use in devices such as organic light emitting diodes, organic photovoltaic devices, organic photosensors, organic transistors and memory array devices. Devices comprising organic materials offer benefits such as low weight, low power consumption and flexibility. Moreover, use of soluble organic materials allows use of solution processing in device manufacture, for example inkjet printing or spin-coating.

A typical organic light-emissive device (“OLED”) is fabricated on a glass or plastic substrate coated with a transparent anode such as indium-tin-oxide (“ITO”). A layer of a thin film of at least one electroluminescent organic material is provided over the first electrode. Finally, a cathode is provided over the layer of electroluminescent organic material. Charge transporting, charge injecting or charge blocking layers may be provided between the anode and the electroluminescent layer and/or between the cathode and the electroluminescent layer.

In operation, holes are injected into the device through the anode and electrons are injected into the device through the cathode. The holes and electrons combine in the organic electroluminescent layer to form excitons which then undergo radiative decay to give light.

A hole-transporting layer may be provided between the anode and the organic light-emitting layer, and/or an electron transporting layer may be provided between the cathode and the organic light-emitting layer to facilitate transport of holes and/or electrons to the light-emitting layer. A hole transporting layer is disclosed in, for example, WO 99/48160.

In WO90/13148 the organic light-emissive material is a conjugated polymer such as poly(phenylenevinylene). In U.S. Pat. No. 4,539,507 the organic light-emissive material is of the class known as small molecule materials, such as tris-(8-hydroxyquinoline) aluminium (“Alq₃”).

These materials electroluminesce by radiative decay of singlet excitons (fluorescence) however spin statistics dictate that up to 75% of excitons are triplet excitons which undergo non-radiative decay, i.e. quantum efficiency may be as low as 25% for fluorescent OLEDs-see, for example, Chem. Phys. Lett., 1993, 210, 61, Nature (London), 2001, 409, 494, Synth. Met., 2002, 125, 55 and references therein.

It has been postulated that the presence of triplet excitons, which may have relatively long-lived triplet excited states, can be detrimental to OLED lifetime as a result of triplet-triplet or triplet-singlet interactions (“lifetime” as used herein in the context of OLED lifetime means the length of time taken for the luminance of an OLED to fall by 50% from an initial luminance value at constant current).

US 2007/145886 discloses an OLED comprising a triplet-quenching material to prevent or reduce triplet-triplet or triplet-singlet interactions.

A hole-transporting layer may be provided between the anode 2 and the light-emitting layer 3

U.S. Pat. No. 5,998,045 disclosed a copolymer comprising anthracene, fluorene and a third component selected from triarylamine, diaryl sulfone and carbazole.

JP 2003-146951 discloses an anthracene-based compound for use in an organic electroluminescent device.

W Cui et al, Chem. Commun., 2008, 1017-1019 discloses a poly(2,6-anthrylene).

US 2007/102695 discloses a polymer comprising a crosslinkable fluorene repeat unit. 9,10-anthracene co-repeat units are disclosed.

### SUMMARY OF THE INVENTION

In a first aspect, the invention provides an organic light-emitting device comprising an anode, a cathode, a light-emitting layer between the anode and the cathode and a hole transporting layer between the anode and the light-emitting layer, wherein the hole transporting layer comprises a hole-transporting material having a triplet energy level, and a triplet-quenching unit having a triplet energy level that is lower than the triplet energy level of the hole-transporting material, with the proviso that the triplet-quenching unit does not comprise fullerene.

Optionally, the triplet-quenching unit is a triplet-quenching material mixed with the hole transporting material.

Optionally, the triplet-quenching unit is chemically bound to the hole transporting material.

Optionally, the hole-transporting material is a polymer and the triplet-quenching unit is provided as a repeat unit in the main chain of the polymer and/or in one or more side chains or one or more end groups of the polymer.

Optionally, the polymer comprises an optionally substituted amine repeat unit.

Optionally, the polymer comprises a repeat unit of formula (V):

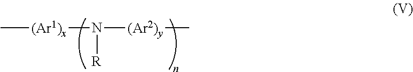

wherein Ar¹ and Ar² in each occurrence are independently selected from optionally substituted aryl or heteroaryl groups, n is greater than or equal to 1, preferably 1 or 2, R is H or a substituent, preferably a substituent; x and y are each independently 1, 2 or 3; and any of the aryl or heteroaryl groups in the repeat unit of Formula (V) may be linked by a direct bond or a divalent linking atom or group.

Optionally, wherein n is 2.

Optionally, each R is independently selected from alkyl, Ar³, or a branched or linear chain of Ar³ groups, preferably —(Ar³)ᵣ, wherein Ar³ in each occurrence is independently selected from optionally substituted aryl or heteroaryl and r is at least 1, optionally 1, 2 or 3.

Optionally, R, Ar¹ and each occurrence of Ar² are each optionally substituted phenyl.

Optionally, the polymer further comprises comprising at least one optionally substituted arylene or heteroarylene repeat unit other than the triplet-quenching repeat unit.

Optionally, the optionally substituted arylene or heteroarylene repeat unit is an optionally substituted fluorene repeat unit.

Optionally, the optionally substituted fluorene repeat unit has formula (IV):

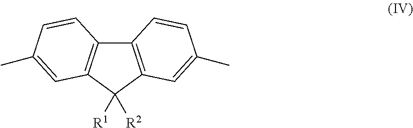

wherein R¹ and R² are independently selected from:

hydrogen;

Ar, wherein Ar is selected from the group consisting of aryl or heteroaryl optionally substituted with one or more substituents selected from halogen; CN; and alkyl wherein one or more non-adjacent C atoms of the alkyl group may be replaced with O, S, N, C═O and —COO and wherein one or more H atoms of the alkyl group may be replaced by a halogen;

alkyl wherein one or more non-adjacent C atoms of the alkyl group may be replaced with O, S, N, C═O and —COO— and wherein one or more H atoms of the alkyl group may be replaced by a halogen or by Ar; and

a crosslinkable group.

Optionally, the triplet-quenching unit is mixed with the hole transporting material.

Optionally, the triplet-quenching unit is bound to the hole transporting material.

Optionally, the hole transporting material is a polymer and the triplet quenching unit is provided as a repeat unit in the polymer backbone, a side chain of the polymer backbone or a polymer end-group.

Optionally, the triplet quenching unit is selected from the group consisting of polyaromatic hydrocarbons such as 2,6-anthracenes, 9,10-anthracenes and derivatives thereof; anthanthrenes and derivatives thereof; distyryl aryls and derivatives thereof such as distyrylbenzenes, distyrylbiphenyls, stilbenes, fulvenes, dibenzofulvenes, perylenes, linear polyenes (from 2 to 6 alkenes) and cyclic polyenes, each of which may optionally be substituted with one or more substituents.

In a second aspect the invention provides a polymer comprising an optionally substituted 2,6-linked anthracene repeat unit and an optionally substituted crosslinkable repeat unit.

Optionally according to the second aspect, the anthracene repeat unit has formula (I):

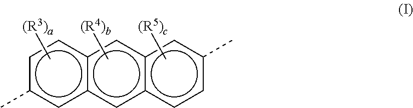

wherein a, b and c are independently 0, 1, 2 or 3 and R³, R⁴ and R⁵ in each occurrence are independently selected from:

Ar, wherein Ar is selected from the group consisting of aryl or heteroaryl optionally substituted with one or more substituents selected from halogen; CN; and alkyl wherein one or more non-adjacent C atoms of the alkyl group may be replaced with O, S, N, C═O and —C(═O)O— and wherein one or more H atoms of the alkyl group may be replaced by a halogen; and

alkyl wherein one or more non-adjacent C atoms of the alkyl group may be replaced with O, S, N, C═O and —COO— and wherein one or more H atoms of the alkyl group may be replaced by a halogen or by Ar.

Optionally according to the second aspect, the anthracene repeat unit has formula (Ia):

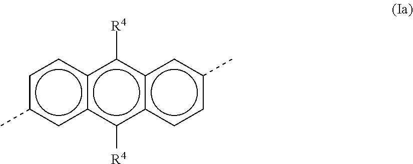

Optionally according to the second aspect, each R⁴ is independently optionally substituted phenyl.

Optionally according to the second aspect, each R⁴ is phenyl substituted by at least one alkyl group.

Optionally according to the second aspect, the polymer comprises an optionally substituted amine repeat unit.

Optionally according to the second aspect, the optionally substituted amine repeat unit has formula (V):

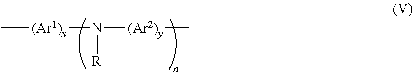

wherein Ar¹ and Ar² in each occurrence are independently selected from optionally substituted aryl or heteroaryl groups, n is greater than or equal to 1, preferably 1 or 2, R is H or a substituent, preferably a substituent; x and y are each independently 1, 2 or 3; and any of the aryl or heteroaryl groups in the repeat unit of Formula (V) may be linked by a direct bond or a divalent linking atom or group.

Optionally according to the second aspect, n is 2.

Optionally according to the second aspect, each R is independently selected from alkyl, Ar³, or a branched or linear chain of Ar³ groups, preferably —(Ar³)ᵣ, wherein Ar³ in each occurrence is independently selected from optionally substituted aryl or heteroaryl and r is at least 1, optionally 1, 2 or 3.

Optionally according to the second aspect, R, Ar¹ and each occurrence of Ar² are each optionally substituted phenyl.

Optionally according to the second aspect, the polymer comprises at least one optionally substituted arylene or heteroarylene repeat unit other than the anthracene repeat unit.

Optionally according to the second aspect, the crosslinkable unit comprises the arylene or heteroarylene repeat unit substituted with a crosslinkable group.

Optionally according to the second aspect, the optionally substituted arylene or heteroarylene repeat unit is an optionally substituted fluorene repeat unit.

Optionally according to the second aspect, the optionally substituted fluorene repeat unit has formula:

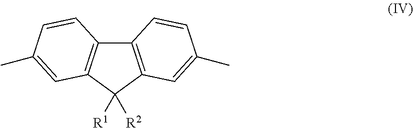

wherein R¹ and R² are independently selected from:

hydrogen;

Ar, wherein Ar is selected from the group consisting of aryl or heteroaryl optionally substituted with one or more substituents selected from halogen; CN; and alkyl wherein one or more non-adjacent C atoms of the alkyl group may be replaced with O, S, N, C═O and —COO and wherein one or more H atoms of the alkyl group may be replaced by a halogen;

alkyl wherein one or more non-adjacent C atoms of the alkyl group may be replaced with O, S, N, C═O and —COO— and wherein one or more H atoms of the alkyl group may be replaced by a halogen or by Ar; and

a crosslinkable group.

Optionally according to the second aspect, the crosslinkable group comprises a crosslinkable benzocyclobutane.

In a third aspect the invention provides a method of forming an organic light-emitting device comprising the steps of:
forming a hole transport layer by depositing a polymer according to the second aspect over an anode from a solution in a solvent;
evaporating the solvent and crosslinking at least some of the crosslinkable repeat units;
forming a light-emitting layer by depositing a light-emitting material over the hole transport layer from a solution in a solvent; and
depositing a cathode over the light-emitting layer.

In a fourth aspect the invention provides a polymer comprising an optionally substituted anthracene repeat unit and an optionally substituted repeat unit of formula:

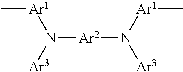

wherein Ar¹ and Ar² each independently represent an optionally substituted aryl or heteroaryl group as described above, and each Ar³ independently represents an aryl or heteroaryl group as described above. The repeat units of the fourth aspect may be as described in the second aspect of the invention, and the polymer of the fourth aspect may comprise any of the further repeat units described with reference to the second aspect.

### DESCRIPTION OF THE DRAWINGS

The invention will now be described in more detail with reference to the drawings, in which:

FIG. 1 illustrates an organic light-emitting device according to an embodiment of the invention;

FIG. 2 illustrates exciton formation in the device of FIG. 1; and

FIG. 3 is a diagram illustrating energy transfer in the device of FIG. 1.

### DETAILED DESCRIPTION OF THE INVENTION

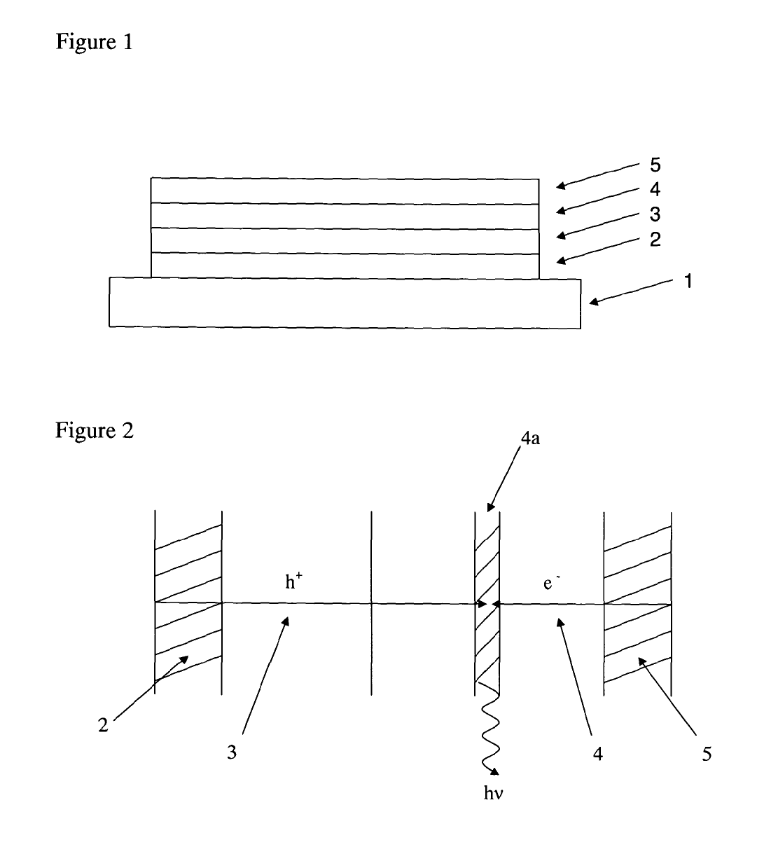

With reference to FIG. 1, an OLED according to an embodiment of the invention comprises a substrate 1 carrying an anode 2, a hole transporting layer 3, an organic light-emitting layer 4 and a cathode 5.

With reference to FIG. 2, in operation holes injected from the anode 2 and electrons injected from the cathode 5 recombine in recombination zone 4a of organic light-emitting layer 4 to form an exciton, and light (hν) is emitted by radiative decay.

However, not all of the excitons that are formed by recombination of holes and electrons undergo radiative decay, and these excitons may be detrimental to device lifetime. In particular, singlet or triplet excitons may migrate from light emitting layer 4 into hole transport layer 3, especially if recombination zone 4a is close to the interface between the hole transport layer 3. Moreover, triplet excitons are typically relatively long-lived species and as such may migrate into hole transport layer 3 even if the recombination zone 4a is relatively distant from the interface between hole transport layer 3 and light emitting layer 4.

Additionally, excitons may be formed in the hole transporting layer 3 from electrons that pass through the light-emitting layer 4 and reach the hole transport layer.

Without wishing to be bound by any theory, it is believed that the presence of excitons in the hole transporting layer may be detrimental to device performance. For example, exciton-exciton interaction may result in formation of super-excited states on the hole-transporting material of the hole-transporting layer, and these highly energetic states may cause a reduction in the operational lifetime and/or efficiency of the device.

The present inventors have found that inclusion of a 2,6-linked anthracene repeat unit in a hole-transporting polymer may improve device performance. Again without wishing to be bound by any theory, it is believed that this improvement may be attributable, at least in part, to acceptance of excitons by the anthracene unit.

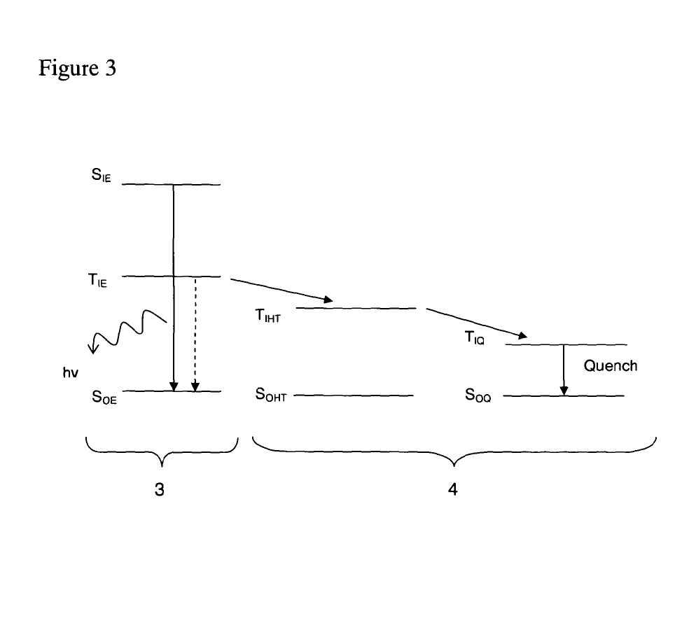

An embodiment of the invention is illustrated in FIG. 3. In this embodiment, a singlet exciton of energy S_{1E} is formed on a light-emitting material in light-emitting layer 4. This exciton decays radiatively to ground state S_{0E} produce fluorescent light. A triplet exciton of energy T_{1E} is also formed on the light-emitting material, however radiative decay of this exciton is formally forbidden. This triplet exciton may migrate into hole-transporting layer 3 and it may be accepted by a hole transporting repeat unit HT of a hole transporting polymer in the hole transporting layer 3 if the triplet energy level T_{1HT} of this repeat unit is lower than T_{1E}.

In order to prevent degradation of the hole transporting repeat unit, a triplet-quenching unit such as a 2,6-anthracene quenching repeat unit is provided which has a triplet excited state energy level T_{1Q} lower than T_{1HT} in order that the triplet exciton may transfer from T_{1HT} to T_{1Q}.

The triplet energy levels of hole-transporting materials and quenching materials may be determined from their phosphorescent spectra as described in, for example, Y. V. Romaovskii et al, Physical Review Letters, 2000, 85 (5), p 1027 and A. van Dijken et al, Journal of the American Chemical Society, 2004, 126, p 7718. Additionally or alternatively, triplet energy levels of numerous materials suitable for use as triplet quenchers can be found in Handbook of Photochemistry, 2^{nd} Edition, Steven L Murov, Ian Carmichael and Gordon L Hug.

Similarly, a singlet exciton on a hole transporting repeat unit of the hole transporting layer 3 may transfer to the 2,6-anthracene repeat unit if the singlet excited state energy level of the hole transporting repeat unit is higher than that of the 2,6-anthracene repeat unit. In this case, the singlet exciton transferred to the 2,6-anthracene repeat unit may undergo radiative (fluorescent) decay.

The 2,6-anthracene repeat unit may optionally be substituted with one or more substituents. Preferred substituents are alkyl.

The triplet-quenching unit may be selected from a range of materials, one or more of which may be used in addition to or as an alternative to the 2,6-anthracene repeat unit, for example aromatic or heteroaromatic compounds comprising one or more mono- or polycyclic rings, and optionally including one or more alkenyl or alkynyl groups, for example polyaromatic hydrocarbons such as 2,6-anthracenes, 9,10-anthracenes and derivatives thereof; anthanthrenes and derivatives thereof; distyryl aryls and derivatives thereof such as distyrylbenzenes, distyrylbiphenyls, stilbenes, fulvenes, dibenzofulvenes, perylenes, linear polyenes (from 2 to 6 alkenes) and cyclic polyenes such as cyclooctatetraene and further materials described in Handbook of Photochemistry, 2^{nd} Edition, Steven L Murov, Ian Carmichael and Gordon L Hug, the contents of which are incorporated herein by reference.

Each said triplet quenching unit may optionally be substituted, for example substituted with one or more substituents selected from:

alkyl wherein one or more non-adjacent C atoms may be replaced with O, S, substituted N, C═O and —COO— and one or more H atoms of the alkyl group may be replaced with F or aryl or heteroaryl optionally substituted with one or more groups R⁴,

aryl or heteroaryl optionally substituted with one or more groups R⁴,

NR⁵₂, OR⁵, SR⁵,

fluorine, nitro and cyano;

wherein each R⁴ is independently alkyl in which one or more non-adjacent C atoms may be replaced with O, S, substituted N, C═O and —COO— and one or more H atoms of the alkyl group may be replaced with F, and each R⁵ is independently selected from the group consisting of alkyl and aryl or heteroaryl optionally substituted with one or more alkyl groups

Preferred substituents include alkyl groups, e.g. C₁₋₂₀ alkyl, or one or more aryl groups, e.g. phenyl, each said aryl substituent optionally being substituted itself, e.g. with one or more alkyl groups.

Exemplary distyryl aryl compounds include the following:

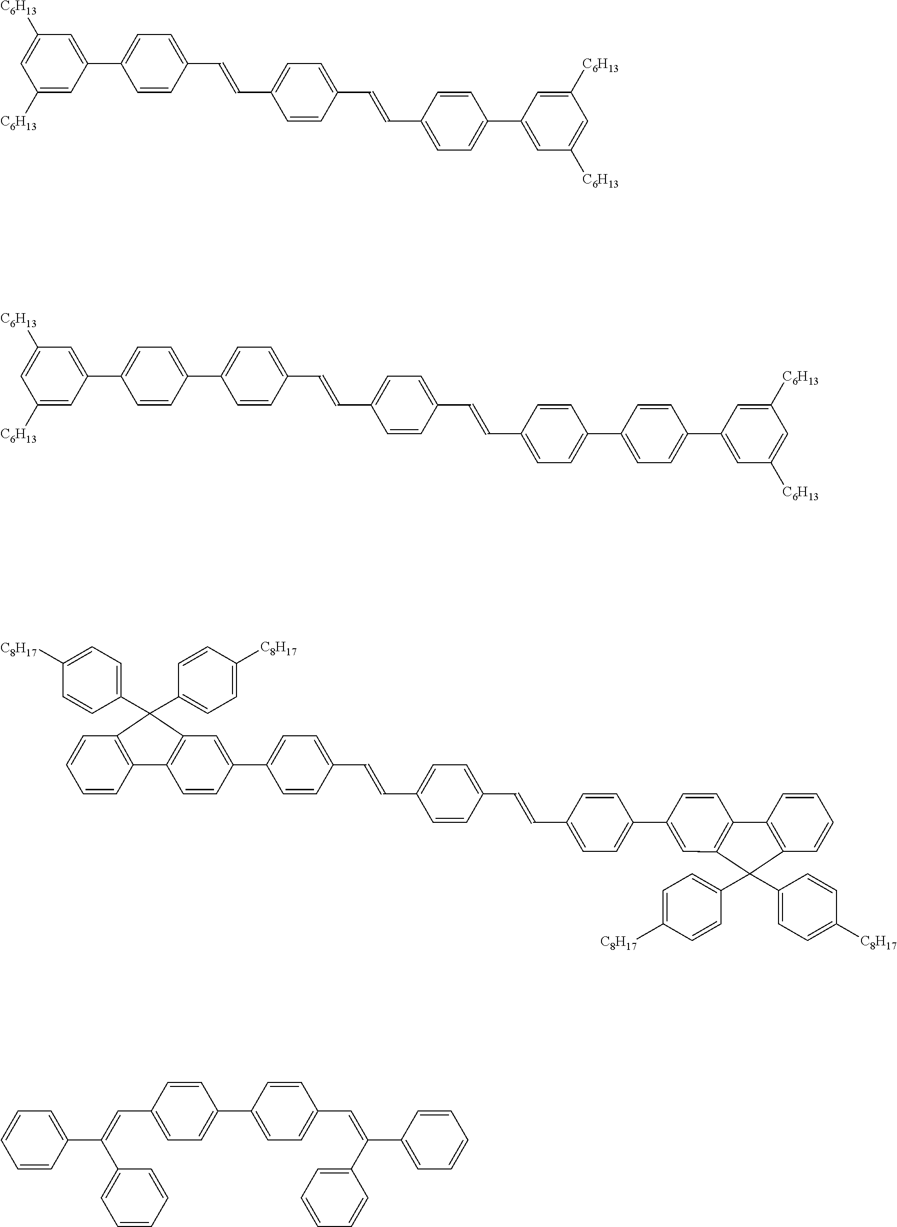

Exemplary anthanthrene compounds include the following:

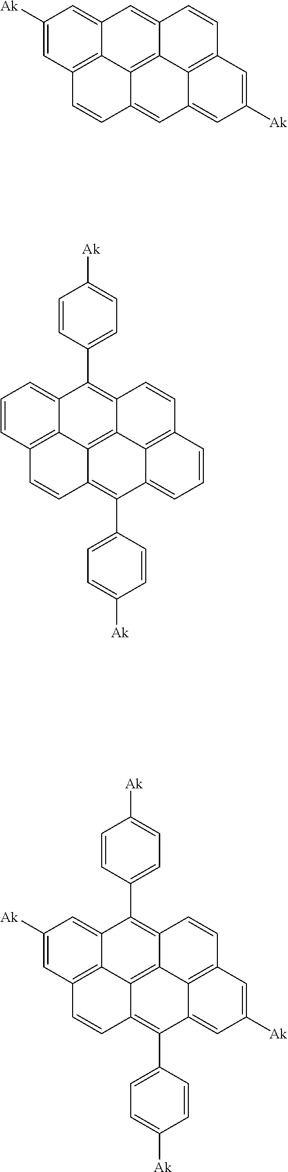

wherein Ak is alkyl, in particular branched or straight chain C₁₋₁₀ alkyl. Particularly preferred alkyl groups are n-butyl, t-butyl, n-hexyl and n-octyl.

Exemplary perylene triplet quenching units have the following formula A:

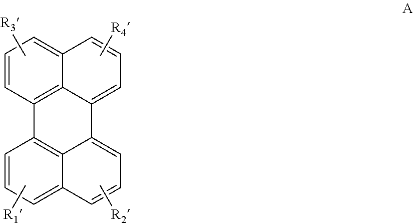

wherein R1′-R4′ are optional substituents, for example substituents selected from the group consisting of alkyl, e.g. C₁₋₂₀ alkyl, optionally substituted aryl, e.g. optionally substituted phenyl, alkoxy, thioether and amine. Preferred substituents are alkyl, more preferably branched alkyl; and phenyl, more preferably alkyl-substituted phenyl. The substituents R1′-R4′ may be present in the 2, 5, 8 and 11 positions. At least one of the R-groups may comprise a linkage to the hole-transporting material.

The triplet-quenching unit may be a compound that is physically mixed with the hole transporting material and any other components that may be present in the composition used to form the hole transporting layer, or it may be bound to the hole transporting material or to one of these other components, where present. In the case where the hole transporting material is a hole transporting polymer, the triplet-quenching unit may be provided as a repeat unit in the polymer main chain, one or more side groups pendant from the polymer main chain, or one or more polymer end-groups.

The triplet-quenching unit may be bound into the main chain of a hole-transporting polymer by polymerising a monomer comprising the triplet accepting repeat unit substituted with at least two polymerisable groups, such as leaving groups capable of participating in a metal-catalysed cross-coupling reaction (it will be appreciated that polymerisation of a monomer comprising more than two leaving groups will create a branch point in the polymer if more than two of the leaving groups react). Substitution of leaving groups on sp² carbon atoms of the triplet-accepting unit may be used for this purpose. Exemplary leaving groups include halogen and boronic acid or ester groups for use in Suzuki or Yamamoto polymerisation reactions, described in more detail below. The triplet-accepting unit may be bound to any repeat unit of the hole transporting polymer. In one embodiment, this polymer comprises a triplet-accepting repeat unit, a hole transporting unit such as a repeat unit of formula (V) described below and an arylene co-repeat unit, for example a repeat unit of formula (IV) described below.

In the case where the hole transporting material is a hole transporting polymer, the perylene may be covalently bound as a side chain to the backbone of the polymer, and it may comprise the following optionally substituted structural unit:

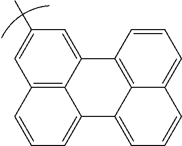

This structural unit may be substituted, for example at any one or more of the positions C2, C5, and C8, as shown below in formula II:

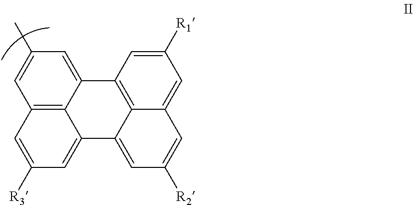

where R₁′, R₂′, and R₃′ each independently represent an optional substituent, as defined above. In one preferred embodiment, all of substituents R₁′, R₂′, and R₃′ are present. R₁′, R₂′, and R₃′ can act to protect the fused rings of the perylene. Optionally, each of R₁′, R₂′, and R₃′ represents t-butyl.

The perylene may be connected to the backbone of the hole-transporting polymer via a spacer group. A spacer group may be conjugated or non-conjugated. Conjugated spacer groups include phenylene, for example. Non-conjugated spacer groups include alkylene, for example.

The perylene may also be directly linked into the polymer backbone.

In one embodiment, it is preferred that the repeat unit in the backbone of the polymer, to which the perylene unit is bound, comprises a fluorene, more preferably a 9,9 disubstituted fluorene. The perylene unit may be provided as a 9-substitutent of a fluorene unit, for example as shown in formulae VII to X:

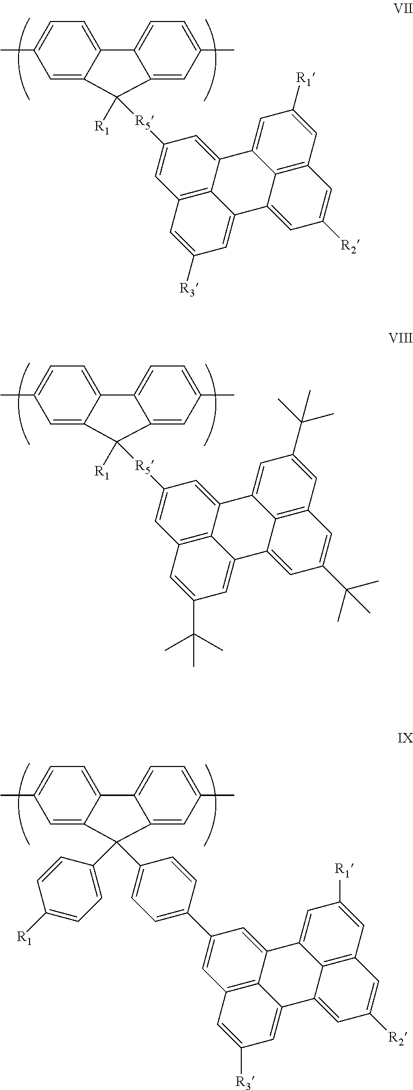

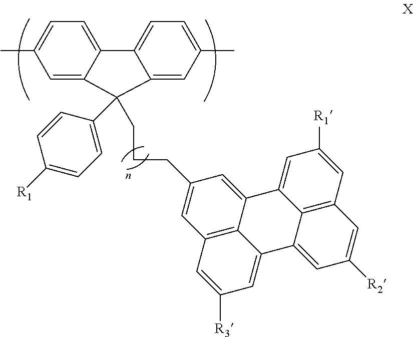

where R₁, R₁′, R₂′, and R₃′ are as defined above; R₅′ is a spacer group, preferably alkylene, arylene (in particular phenylene), oxygen, nitrogen, sulphur or combinations thereof, in particular arylalkyl; and n is from 1-10.

R₁ represents H or a substituent, for example an optionally substituted C₁-C₂₀ alkyl or aryl group.

Referring to the embodiment where the perylene unit is provided as a repeat unit in the backbone of the conjugated polymer, the perylene unit may be directly bound to adjacent repeat units or it may be bound via spacer groups. The perylene unit may be bound through any position, and substituted at any position. Preferred repeat units according to this embodiment include formulae XI and XII:

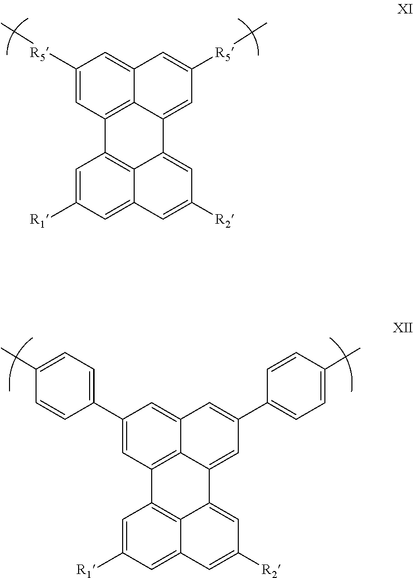

wherein R1′, R2′ and R5′ are as defined above.

Formulae XI and XII illustrate linkage of the perylene unit through its 8 and 11 positions, however it will be appreciated that analogous repeat units may be provided wherein the unit is linked through any combination of two of the 2, 5, 8 and 11 positions.

Referring to the embodiment where the perylene unit is covalently bound as end group of the hole transporting polymer, preferred end groups have formulae XIII and XIV:

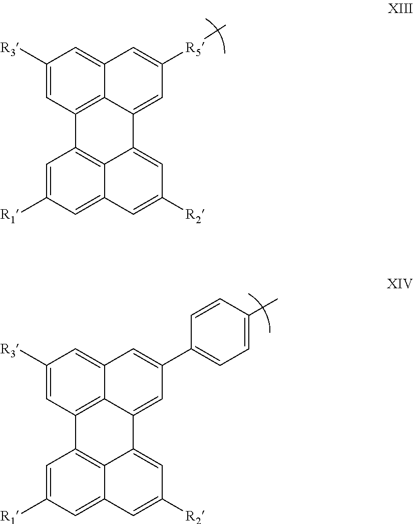

wherein R1′, R2′, R3′ and R5′ are as defined above.

The polymer is preferably a linear polymer, and the perylene end group is present at one or both ends of the polymer chain.

Some examples of suitable perylene monomers for manufacturing the hole transporting polymer are given below:

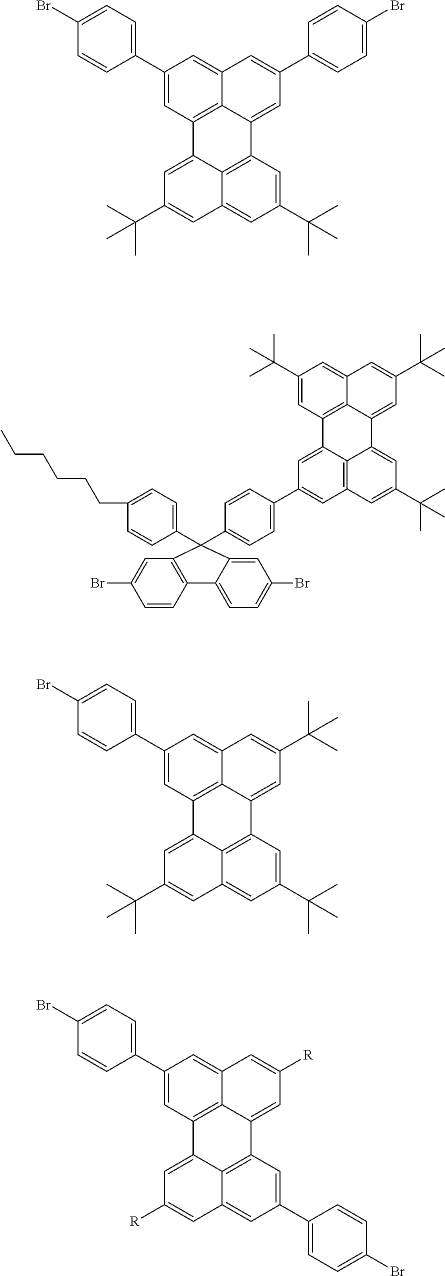

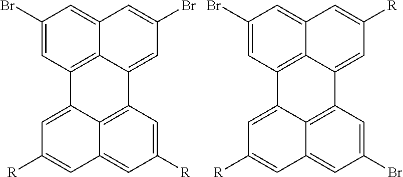

Exemplary triplet-quenching anthanthrene repeat units include the following:

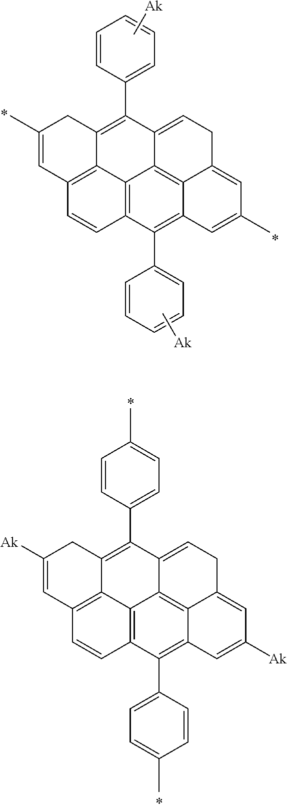

wherein * denotes the linking points for linking the repeat unit into the polymer chain, and Ak is alkyl, in particular branched or straight chain C₁₋₁₀ alkyl. Particularly preferred alkyl groups are n-butyl, t-butyl, n-hexyl and n-octyl.

The triplet-accepting unit may be provided as a side-group or end-group of a hole transporting polymer by reacting a compound substituted with one polymerisable group, such as a leaving group capable of participating in a metal-catalysed cross-coupling reaction, such as a halogen or boronic acid or ester, with a leaving group on the polymer.

Alternatively, a side-group may be incorporated into a hole-transporting polymer by providing it as a substituent of a monomer as illustrated below:

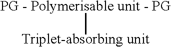

wherein PG represents a polymerisable group such as a leaving group as described above, or a polymerisable double bond.

A wide range of further repeat units may be present in the polymer, and exemplary further repeat units of the polymer are described below.

Hole Transporting Repeat Unit

Suitable hole transporting repeat units may be units that provide the hole transporting layer of a device with a HOMO level that is within about 0.5 eV, optionally about 0.3 eV of the workfunction of the anode or the workfunction or HOMO level of a layer between the anode and the hole-transporting layer (such as a hole-injection layer). The hole-transporting repeat unit may provide the hole transporting polymer with a HOMO level that is shallower (i.e. closer to vacuum) than that of the anode or of a layer between the anode and the hole-transporting layer. The hole transporting polymer may provide the hole-transporting layer with a HOMO level within about 0.3 eV of the HOMO of the light-emitting layer in order to provide efficient hole transport from the hole transporting layer into the light-emitting layer. The HOMO level of the hole-transporting polymer may be measured by cyclic voltammetry, for example.

Exemplary hole transporting repeat units of the polymer include arylamine repeat units, in particular repeat units of formula (V):

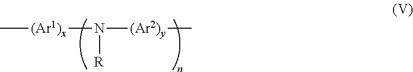

wherein Ar¹ and Ar² in each occurrence are independently selected from optionally substituted aryl or heteroaryl groups, n is greater than or equal to 1, preferably 1 or 2, R is H or a substituent, preferably a substituent, and x and y are each independently 1, 2 or 3.

“Aryl(ene)” and “heteroaryl(ene)” as used herein includes both fused and unfused aryl and heteroaryl groups respectively.

R is preferably alkyl, Ar³, or a branched or linear chain of Ar³ groups, for example —(Ar³)ᵣ, wherein Ar³ in each occurrence is independently selected from aryl or heteroaryl and r is at least 1, optionally 1, 2 or 3.

Any of Ar¹, Ar² and Ar³ may independently be substituted with one or more substituents. Preferred substituents are selected from the group R³ consisting of:
alkyl wherein one or more non-adjacent C atoms may be replaced with O, S, substituted N, C═O and —COO— and one or more H atoms of the alkyl group may be replaced with F or aryl or heteroaryl optionally substituted with one or more groups R⁴,
aryl or heteroaryl optionally substituted with one or more groups R⁴,
NR⁵₂, OR⁵, SR⁵,
fluorine, nitro and cyano;

wherein each R⁴ is independently alkyl in which one or more non-adjacent C atoms may be replaced with O, S, substituted N, C═O and —COO— and one or more H atoms of the alkyl group may be replaced with F, and each R⁵ is independently selected from the group consisting of alkyl and aryl or heteroaryl optionally substituted with one or more alkyl groups.

R may comprise a crosslinkable-group, for example as described below.

Any of the aryl or heteroaryl groups in the repeat unit of Formula (V) may be linked by a direct bond or a divalent linking atom or group. Preferred divalent linking atoms and groups include O, S; substituted N; and substituted C.

Where present, substituted N or substituted C of R³, R⁴ or of the divalent linking group may independently in each occurrence be NR⁶ or CR⁶₂ respectively wherein R⁶ is alkyl or optionally substituted aryl or heteroaryl. Optional substituents for aryl or heteroaryl groups R⁶ may be selected from R⁴ or R⁵.

In one preferred arrangement, R is Ar³ and each of Ar¹, Ar² and Ar³ are independently and optionally substituted with one or more C₁₋₂₀ alkyl groups.

Particularly preferred units satisfying Formula I include units of Formulae I-3:

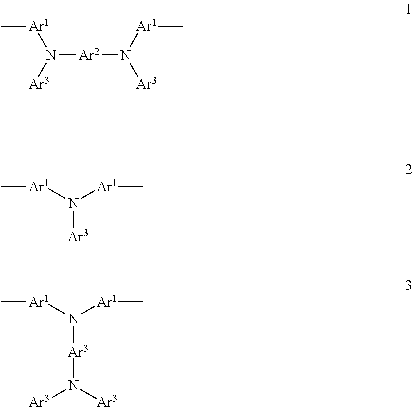

wherein Ar¹ and Ar² are as defined above; and Ar³ is optionally substituted aryl or heteroaryl. Where present, preferred substituents for Ar³ include substituents as described for Ar¹ and Ar², in particular alkyl and alkoxy groups.

Ar² and Ar³ are preferably phenyl, each of which may independently be substituted with one or more substituents as described above.

In another preferred arrangement, aryl or heteroaryl groups of formula (V) are phenyl, each phenyl group being optionally substituted with one or more alkyl groups.

In another preferred arrangement, Ar¹, Ar² and Ar³ are phenyl, each of which may be substituted with one or more C₁₋₂₀ alkyl groups, and r=1.

In another preferred arrangement, Ar¹ and Ar² are phenyl, each of which may be substituted with one or more C₁₋₂₀ alkyl groups, and R is 3,5-diphenylbenzene wherein each phenyl may be substituted with one or more alkyl groups.

In yet another preferred arrangement, Ar', Ar² and Ar³ are phenyl, each of which may be substituted with one or more C₁₋₂₀ alkyl groups, r=1 and Ar¹ and Ar² are linked by an O or S atom.

In yet another preferred arrangement, Ar', Ar² and Ar³ are phenyl, each of which may be substituted with one or more C₁₋₂₀ alkyl groups, r, x and y are all 1, n=2 and Ar¹ and Ar² are linked by an O or S atom.

Further Repeat Units

In addition to the optionally substituted 2,6-anthracene repeat unit, the polymer may further comprise another optionally substituted arylene repeat unit or an optionally substituted heteroarylene repeat unit. Exemplary arylene repeat units are disclosed in for example, Adv. Mater. 2000 12(23) 1737-1750 and include: 1,4-phenylene repeat units as disclosed in J. Appl. Phys. 1996, 79, 934; fluorene repeat units as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorine, nitro or cyano; and substituents for increasing glass transition temperature (Tg) of the polymer.

Particularly preferred arylene repeat units comprise optionally substituted, 2,7-linked fluorenes, most preferably repeat units of formula IV:

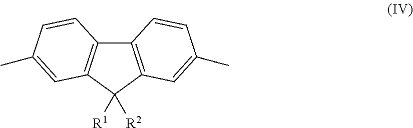

wherein R¹ and R² are independently H or a substituent and wherein R¹ and R² may be linked to form a ring. R¹ and R² are preferably selected from the group consisting of hydrogen; optionally substituted alkyl wherein one or more non-adjacent C atoms may be replaced with O, S, N, C═O and —COO—; optionally substituted aryl or heteroaryl, in particular aryl or heteroaryl substituted with one or more alkyl groups, e.g. C₁₋₂₀ alkyl; and optionally substituted arylalkyl or heteroarylalkyl. More preferably, at least one of R¹ and R² comprises an optionally substituted alky, e.g. C₁-C₂₀ alkyl, or aryl, in particular phenyl, group. R¹ and R² may each independently comprise a linear or branched chain of aryl or heteroaryl groups, each of which groups may independently be substituted, for example a group of formula (Ar³)ᵣ as described above.

In the case where R¹ or R² comprises aryl or heteroaryl, preferred optional substituents include alkyl groups wherein one or more non-adjacent C atoms may be replaced with O, S, N, C═O and —COO—.

R¹ and/or R² may comprise a crosslinkable-group, for example as described below. A cross-linkable group may be spaced from the fluorene unit by a spacer group, for example an optionally substituted alkyl group in which one or more non-adjacent C atoms may be replaced with O, S, N, C═O and —C(═O)O—.

Optional substituents for the fluorene unit, other than substituents R¹ and R², are preferably selected from the group consisting of alkyl wherein one or more non-adjacent C atoms may be replaced with O, S, N, C═O and —COO—, optionally substituted aryl, optionally substituted heteroaryl, alkoxy, alkylthio, fluorine, cyano and arylalkyl.

Cross-Linking Groups and Repeat Units

The cross-linking repeat unit may be provided as any one of the aforementioned repeat units substituted with a cross-linkable group, for example as described above specifically with reference to repeat units of formulae (IV) and (V). Suitable cross-linking groups include groups comprising cross-linkable double bonds such as optionally substituted acrylate or vinyl groups, in particular groups comprising a terminal (═CH₂) double bond, optionally substituted (including fused) oxetane and optionally substituted (including fused) cyclobutanes, for example benzocyclobutane.

Polymerisation Methods

Preferred methods for preparation of conjugated charge-transporting polymers comprise a “metal insertion” wherein the metal atom of a metal complex catalyst is inserted between an aryl or heteroaryl group and a leaving group of a monomer. Exemplary metal insertion methods are Suzuki polymerisation as described in, for example, WO 00/53656 and Yamamoto polymerisation as described in, for example, T. Yamamoto, “Electrically Conducting And Thermally Stable π-Conjugated Poly(arylene)s Prepared by Organometallic Processes”, Progress in Polymer Science 1993, 17, 1153-1205. In the case of Yamamoto polymerisation, a nickel complex catalyst is used; in the case of Suzuki polymerisation, a palladium complex catalyst is used.

For example, in the synthesis of a linear polymer by Yamamoto polymerisation, a monomer having two reactive halogen groups is used. Similarly, according to the method of Suzuki polymerisation, at least one reactive group is a boron derivative group such as a boronic acid or boronic ester and the other reactive group is a halogen. Preferred halogens are chlorine, bromine and iodine, most preferably bromine.

It will therefore be appreciated that repeat units illustrated throughout this application may be derived from a monomer carrying suitable leaving groups. Likewise, an end group or side group may be bound to the polymer by reaction of a suitable leaving group.

Suzuki polymerisation may be used to prepare regioregular, block and random copolymers. In particular, homopolymers or random copolymers may be prepared when one reactive group is a halogen and the other reactive group is a boron derivative group. Alternatively, block or regioregular, in particular AB, copolymers may be prepared when both reactive groups of a first monomer are boron and both reactive groups of a second monomer are halogen.

As alternatives to halides, other leaving groups capable of participating in metal insertion include groups include tosylate, mesylate and triflate.

Light Emitting Layer

Suitable light-emitting materials for use in the light-emitting layer include small molecule, polymeric and dendrimeric materials, and compositions thereof. Suitable light-emitting polymers for use in layer 3 include conjugated polymers, for example optionally substituted poly(arylene vinylenes) such as polyp-phenylene vinylenes) and optionally substituted polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater. 2000 12(23) 1737-1750 and references therein.

Polymers for use as light-emitting materials in devices according to the present invention may comprise a repeat unit selected from optionally substituted arylene or heteroarylene repeat units as described above, in particular fluorene repeat units of formula (IV) described above.

A light-emitting polymer, in particular a blue light-emitting polymer, may comprise an optionally substituted arylene or heteroarylene repeat unit as described above and an arylamine repeat unit, in particular a repeat unit of formula (V) as described above.

The light-emitting layer may consist of a light-emitting material alone, or may comprise this material in combination with one or more further materials. In particular, the light-emitting polymer may be blended with hole and/or electron transporting materials or alternatively may be covalently bound to hole and/or electron transporting materials as disclosed in for example, WO 99/48160.

Light-emitting copolymers may comprise a light-emitting region and at least one of a hole transporting region and an electron transporting region as disclosed in, for example, WO 00/55927 and U.S. Pat. No. 6,353,083. If only one of a hole transporting region and electron transporting region is provided then the electroluminescent region may also provide the other of hole transport and electron transport functionality—for example, an amine unit as described above may provide both hole transport and light-emission functionality. A light-emitting copolymer comprising light-emitting repeat units and one or both of a hole transporting repeat units and electron transporting repeat units may provide said units in a polymer main-chain, as per U.S. Pat. No. 6,353,083, or in polymer side-groups pendant from the polymer backbone.

The light emitting layer may comprise a host material and at least one light-emitting dopant. The host material may be a material as described above that would, in the absence of a dopant, emit light itself. When a host material and dopant are used in a device, the dopant alone may emit light. Alternatively, the host material and one or more dopants may emit light. White light may be generated by emission from multiple light sources, such as emission from both the host and one or more dopants or emission from multiple dopants.

In the case of a fluorescent light-emitting dopant the singlet excited state energy level (S₁) of the host material should be higher than that of the fluorescent light-emitting dopant in order that singlet excitons may be transferred from the host material to the fluorescent light-emitting dopant. Likewise, in the case of a phosphorescent light-emitting dopant the triplet excited state energy level (T₁) of the host material should be higher than that of the phosphorescent light-emitting dopant in order that triplet excitons may be transferred from the host material to the fluorescent light-emitting dopant.

The light-emitting dopant may be physically mixed with the host material or it may be chemically bound to the host material in the same manner described above with respect to binding of the light-emitting dopant to the charge transporting material. Suitable light-emitting dopants are described in more detail below.

The light-emitting layer may be patterned or unpatterned. A device comprising an unpatterned layer may be used an illumination source, for example. A white light emitting device is particularly suitable for this purpose. A device comprising a patterned layer may be, for example, an active matrix display or a passive matrix display. In the case of an active matrix display, a patterned electroluminescent layer is typically used in combination with a patterned anode layer and an unpatterned cathode. In the case of a passive matrix display, the anode layer is formed of parallel stripes of anode material, and parallel stripes of electroluminescent material and cathode material arranged perpendicular to the anode material wherein the stripes of electroluminescent material and cathode material are typically separated by stripes of insulating material (“cathode separators”) formed by photolithography.

Light-Emitting Dopants

Materials that may be used as fluorescent or phosphorescent light-emitting dopants in the light-emitting layer include metal complexes comprising optionally substituted complexes of formula (III):

ML¹_{q}L²ᵣL³ₛ (III)

wherein M is a metal; each of L¹, L² and L³ is a coordinating group; q is an integer; r and s are each independently 0 or an integer; and the sum of (a·q)+(b·r)+(c·s) is equal to the number of coordination sites available on M, wherein a is the number of coordination sites on L¹, b is the number of coordination sites on L² and c is the number of coordination sites on L³.

Heavy elements M induce strong spin-orbit coupling to allow rapid intersystem crossing and emission from triplet or higher states (phosphorescence). Suitable heavy metals M include:
lanthanide metals such as cerium, samarium, europium, terbium, dysprosium, thulium, erbium and neodymium; and
d-block metals, in particular those in rows 2 and 3 i.e. elements 39 to 48 and 72 to 80, in particular ruthenium, rhodium, palladium, rhenium, osmium, iridium, platinum and gold. Iridium is particularly preferred.

Suitable coordinating groups for the f-block metals include oxygen or nitrogen donor systems such as carboxylic acids, 1,3-diketonates, hydroxy carboxylic acids,

Schiff bases including acyl phenols and iminoacyl groups. As is known, luminescent lanthanide metal complexes require sensitizing group(s) which have the triplet excited energy level higher than the first excited state of the metal ion. Emission is from an f-f transition of the metal and so the emission colour is determined by the choice of the metal. The sharp emission is generally narrow, resulting in a pure colour emission useful for display applications.

The d-block metals are particularly suitable for emission from triplet excited states. These metals form organometallic complexes with carbon or nitrogen donors such as porphyrin or bidentate ligands of formula (VI):

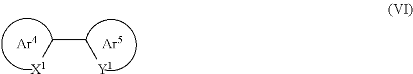

wherein Ar⁴ and Ar⁵ may be the same or different and are independently selected from optionally substituted aryl or heteroaryl; X¹ and Y¹ may be the same or different and are independently selected from carbon or nitrogen; and Ar⁴ and Ar⁵ may be fused together. Ligands wherein X¹ is carbon and Y¹ is nitrogen are particularly preferred.

Examples of bidentate ligands are illustrated below:

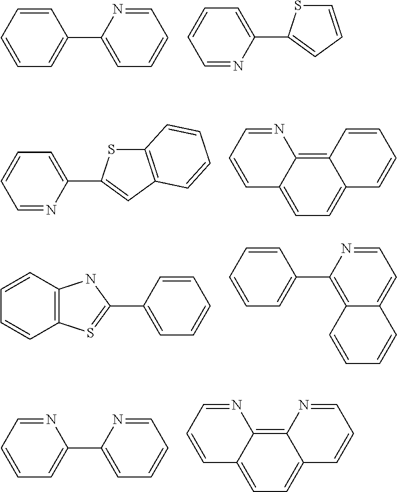

Each of Ar⁴ and Ar⁵ may carry one or more substituents. Two or more of these substituents may be linked to form a ring, for example an aromatic ring. Particularly preferred substituents include fluorine or trifluoromethyl which may be used to blue-shift the emission of the complex as disclosed in WO 02/45466, WO 02/44189, US 2002-117662 and US 2002-182441; alkyl or alkoxy groups as disclosed in JP 2002-324679; carbazole which may be used to assist hole transport to the complex when used as an emissive material as disclosed in WO 02/81448; bromine, chlorine or iodine which can serve to functionalise the ligand for attachment of further groups as disclosed in EP 1245659; and dendrons which may be used to obtain or enhance solution processability of the metal complex as disclosed in WO 02/66552.

A light-emitting dendrimer typically comprises a light-emitting core bound to one or more dendrons, wherein each dendron comprises a branching point and two or more dendritic branches. Preferably, the dendron is at least partially conjugated, and at least one of the core and dendritic branches comprises an aryl or heteroaryl group.

Other ligands suitable for use with d-block elements include diketonates, in particular acetylacetonate (acac); triarylphosphines and pyridine, each of which may be substituted.

Main group metal complexes show ligand based, or charge transfer emission. For these complexes, the emission colour is determined by the choice of ligand as well as the metal.

A wide range of fluorescent low molecular weight metal complexes are known and have been demonstrated in organic light emitting devices [see, e.g., Macromol. Sym. 125 (1997) 1-48, U.S. Pat. No. 5,150,006, U.S. Pat. No. 6,083,634 and U.S. Pat. No. 5,432,014]. Suitable ligands for di or trivalent metals include: oxinoids, e.g. with oxygen-nitrogen or oxygen-oxygen donating atoms, generally a ring nitrogen atom with a substituent oxygen atom, or a substituent nitrogen atom or oxygen atom with a substituent oxygen atom such as 8-hydroxyquinolate and hydroxyquinoxalinol-10-hydroxybenzo (h) quinolinato (II), benzazoles (III), schiff bases, azoindoles, chromone derivatives, 3-hydroxyflavone, and carboxylic acids such as salicylato amino carboxylates and ester carboxylates. Optional substituents include halogen, alkyl, alkoxy, haloalkyl, cyano, amino, amido, sulfonyl, carbonyl, aryl or heteroaryl on the (hetero) aromatic rings which may modify the emission colour.

Additional Layers

The OLED may comprise layers between the anode and the cathode other than hole-transporting layer 3 and light-emitting layer 4, examples of which are described below.

A conductive hole injection layer, which may be formed from a conductive organic or inorganic material, may be provided between the anode and the light-emitting layer to assist hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

One or more further charge transporting or blocking layers may also be provided, for example additional hole transporting layers, one or more electron transporting layers, one or more electron-blocking layers and one or more hole-blocking layers.

Cathode

The cathode 5 is selected from materials that have a workfunction allowing injection of electrons into the electroluminescent layer. Other factors influence the selection of the cathode such as the possibility of adverse interactions between the cathode and the light-emitting material of the light-emitting layer, in particular if the cathode and light-emitting layer are in direct contact. The cathode 5 may consist of a single material such as a layer of aluminium. Alternatively, it may comprise a plurality of metals, for example a bilayer of a low workfunction material and a high workfunction material such as calcium and aluminium as disclosed in WO 98/10621; elemental barium as disclosed in WO 98/57381, Appl. Phys. Lett. 2002, 81(4), 634 and WO 02/84759; or a thin layer of metal compound, in particular an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode will comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

Encapsulation

OLEDs devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device is preferably encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric as disclosed in, for example, WO 01/81649 or an airtight container as disclosed in, for example, WO 01/19142. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

Solution Processing

The hole-transporting layer 3 and the light-emitting layer 4 may be deposited by any process, including vacuum evaporation and deposition from a solution in a solvent.

Upon deposition of the hole-transporting polymer to form hole transporting layer 3, the crosslinkable repeat unit of the hole transporting polymer may be crosslinked in order to render the polymer substantially insoluble and thereby allow formation of a light-emitting layer 5 by a solution processing method with substantially no dissolution of the hole transporting polymer by the solvent used to deposit the light-emitting layer 5. The crosslinkable repeat unit may be crosslinked by any suitable means, for example by UV irradiation or heating.

In the case where one or both of hole-transporting layer 3 and the light-emitting layer 4 comprise a polyarylene, such as a polyfluorene, suitable solvents for solution deposition include mono- or poly-alkylbenzenes such as toluene and xylene. Particularly preferred solution deposition techniques including printing and coating techniques, preferably spin-coating and inkjet printing.

Spin-coating is particularly suitable for devices wherein patterning of the light-emitting material is unnecessary—for example for lighting applications or simple monochrome segmented displays.

Inkjet printing is particularly suitable for high information content displays, in particular full colour displays. A device may be inkjet printed by providing a patterned layer over the first electrode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

Other solution deposition techniques include dip-coating, roll printing and screen printing.

### EXAMPLES

### Monomer Synthesis

A triplet-quenching monomer may be prepared according to the following process starting from dibromoanthraquinone available from, for example, TCI Europe:

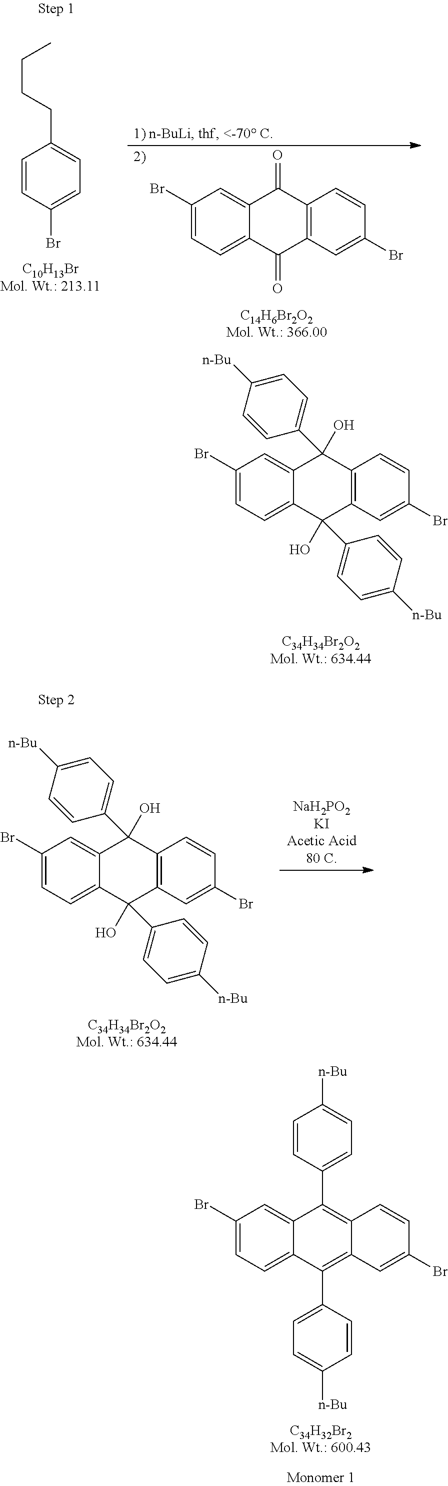

### Polymer Example 1

A hole-transporting polymer was formed by polymerisation of the following monomers with 2 mol % of Monomer 1 by Suzuki polymerisation as described in WO 00/53656:

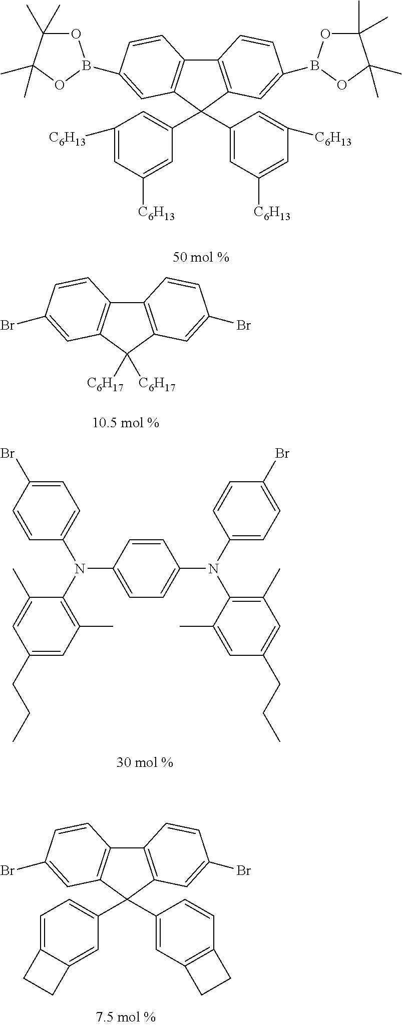

The polymer had a weight-average molecular weight of 458,000 and a number-average molecular weight of 96,000.

### Comparative Polymer 1

For the purpose of comparison, the same polymer was formed but in which the 2 mol % of Monomer 1 was replaced with 2 mol % of 2,7-dibromo-9,9-dioctylfluorene.

### Device Example 1

An organic light-emitting device having the following structure was formed:

ITO/HIL/HTL/LE/Cathode

wherein HIL is a hole-injecting layer comprising a hole-injecting material, HTL is a hole-transporting layer formed by spin-coating Polymer Example 1 to a thickness of about 20 nm; LE is a white light-emitting layer comprising a light-emitting polymer comprising fluorene repeat units of formula (IV) and blue and green light-emitting amine repeat units of formula (V) blended with a red phosphorescent material formed to a thickness of about 70 nm; and the cathode comprises a trilayer of a metal fluoride up to a thickness of about 5 nm, aluminium (about 200 nm) and silver (about 100 nm).

For the purpose of comparison, Comparative Device 1 was formed as above but with Comparative Polymer 1 in place of Polymer Example 1. Results are summarised in the table below, in which T80 is the time taken for luminance of the device to fall to 80% of its initial value at constant current, and CIE (x,y) are co-ordinates on the CIE 1931 colour space chromaticity diagram.

| | Device Example 1 | Comparative Device 1 |
|---|---|---|
| T80 | 716 | 463 |
| CIE (x, y) | (0.315, 0.320) | (0.289, 0.321) |

The T80 of the device is increased by about 50% upon inclusion of a 2,6-anthracene repeat unit in the polymer. Moreover, although light is emitted from the hole-transport layer arising from fluorescence of the 2,6-anthracene repeat unit, there is very little change in colour emitted by the device overall.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. An organic light-emitting device comprising an anode, a cathode, a light-emitting layer between the anode and the cathode and a hole transporting layer between the anode and the light-emitting layer, wherein the hole transporting layer comprises a hole-transporting material having a triplet energy level, and a triplet-quenching unit having a triplet energy level that is lower than the triplet energy level of the hole-transporting material, with the proviso that the triplet-quenching unit does not comprise fullerene.

2. An organic light-emitting device according to claim 1 wherein the triplet-quenching unit is a triplet-quenching material mixed with the hole transporting material.

3. An organic light-emitting device according to claim 1 wherein the triplet-quenching unit is chemically bound to the hole transporting material.

4. An organic light-emitting device according to claim 3 wherein the hole-transporting material is a polymer and the triplet-quenching unit is provided as a repeat unit in the main chain of the polymer and/or in one or more side chains or one or more end groups of the polymer.

5. An organic light-emitting device according to claim 4 wherein the polymer comprises an optionally substituted amine repeat unit.

6. An organic light-emitting device according to claim 5 wherein the polymer comprises an repeat unit of formula (V): 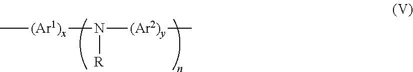
wherein Ar¹ and Ar² in each occurrence are independently selected from optionally substituted aryl or heteroaryl groups, n is greater than or equal to 1, preferably 1 or 2, R is H or a substituent, preferably a substituent; x and y are each independently 1, 2 or 3; and any of the aryl or heteroaryl groups in the repeat unit of Formula (V) may be linked by a direct bond or a divalent linking atom or group.

7. An organic light-emitting device according to claim 6 wherein n is 2.

8. An organic light-emitting device according to claim 6 wherein each R is independently selected from alkyl, Ar³, or a branched or linear chain of Ar³ groups, preferably —(Ar³)ᵣ, wherein Ar³ in each occurrence is independently selected from optionally substituted aryl or heteroaryl and r is at least 1, optionally 1, 2 or 3.

9. An organic light-emitting device according to claim 8 wherein, R, Ar¹ and each occurrence of Ar² are each optionally substituted phenyl.

10. An organic light-emitting device according to claim 4 wherein the polymer further comprises comprising at least one optionally substituted arylene or heteroarylene repeat unit other than the triplet-quenching repeat unit.

11. An organic light-emitting device according to claim 10 wherein the optionally substituted arylene or heteroarylene repeat unit is an optionally substituted fluorene repeat unit.

12. A polymer according to claim 11 wherein the optionally substituted fluorene repeat unit has formula (IV): 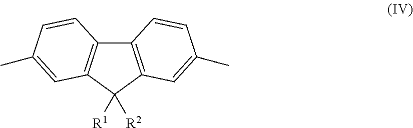
wherein R¹ and R² are independently selected from:
hydrogen;
Ar, wherein Ar is selected from the group consisting of aryl or heteroaryl optionally substituted with one or more substituents selected from halogen; CN; and alkyl wherein one or more non-adjacent C atoms of the alkyl group may be replaced with O, S, N, C═O and —COO and wherein one or more H atoms of the alkyl group may be replaced by a halogen;
alkyl wherein one or more non-adjacent C atoms of the alkyl group may be replaced with O, S, N, C═O and —COO— and wherein one or more H atoms of the alkyl group may be replaced by a halogen or by Ar; and
a crosslinkable group.

13. An organic light-emitting device according to claim 1, wherein the triplet-quenching unit is mixed with the hole transporting material.

14. An organic light-emitting device according to claim 1 wherein the triplet-quenching unit is bound to the hole transporting material.

15. An organic light-emitting device according to claim 14 wherein the hole transporting material is a polymer and the triplet quenching unit is provided as a repeat unit in the polymer backbone, a side chain of the polymer backbone or a polymer end-group.

16. An organic light-emitting device according to claim 1, wherein the triplet quenching unit is selected from the group consisting of polyaromatic hydrocarbons such as 2,6-anthracenes, 9,10-anthracenes and derivatives thereof; anthanthrenes and derivatives thereof; distyryl aryls and derivatives thereof such as distyrylbenzenes, distyrylbiphenyls, stilbenes, fulvenes, dibenzofulvenes, perylenes, linear polyenes (from 2 to 6 alkenes) and cyclic polyenes, each of which may optionally be substituted with one or more substituents.

17. A polymer comprising an optionally substituted 2,6-linked anthracene repeat unit and an optionally substituted crosslinkable repeat unit.

18. A polymer according to claim 17 wherein the anthracene repeat unit has formula (I): 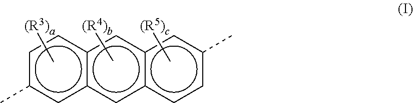
wherein a, b and c are independently 0, 1, 2 or 3 and R³, R⁴ and R⁵ in each occurrence are independently selected from:
Ar, wherein Ar is selected from the group consisting of aryl or heteroaryl optionally substituted with one or more substituents selected from halogen; CN; and alkyl wherein one or more non-adjacent C atoms of the alkyl group may be replaced with O, S, N, C═O and —C(═O)O— and wherein one or more H atoms of the alkyl group may be replaced by a halogen; and
alkyl wherein one or more non-adjacent C atoms of the alkyl group may be replaced with O, S, N, C═O and —COO— and wherein one or more H atoms of the alkyl group may be replaced by a halogen or by Ar.

19. A polymer according to claim 18 wherein the anthracene repeat unit has formula (Ia):

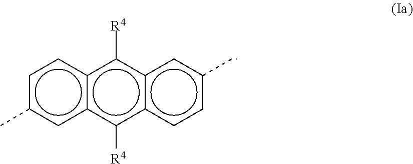

20. A polymer according to claim 18 wherein b is 2 and each R⁴ is independently optionally substituted phenyl.

21. A polymer according to claim 20 wherein each R⁴ is phenyl substituted by at least one alkyl group.

22. A polymer according to claim 17 further comprising an optionally substituted amine repeat unit.

23. A polymer according to claim 22 wherein the optionally substituted amine repeat unit has formula (V): 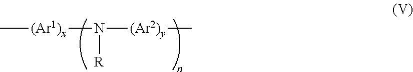
wherein Ar¹ and Ar² in each occurrence are independently selected from optionally substituted aryl or heteroaryl groups, n is greater than or equal to 1, preferably 1 or 2, R is H or a substituent, preferably a substituent; x and y are each independently 1, 2 or 3; and any of the aryl or heteroaryl groups in the repeat unit of Formula (V) may be linked by a direct bond or a divalent linking atom or group.

24. A polymer according to claim 23 wherein n is 2.

25. A polymer according to claim 23 wherein each R is independently selected from alkyl, Ar³, or a branched or linear chain of Ar³ groups, preferably —(Ar³)ᵣ, wherein Ar³ in each occurrence is independently selected from optionally substituted aryl or heteroaryl and r is at least 1, optionally 1, 2 or 3.

26. A polymer according to claim 25 wherein, R, Ar¹ and each occurrence of Ar² are each optionally substituted phenyl.

27. A polymer according to claim 17 comprising at least one optionally substituted arylene or heteroarylene repeat unit other than the anthracene repeat unit.

28. A polymer according to claim 27 wherein the crosslinkable unit comprises the arylene or heteroarylene repeat unit substituted with a crosslinkable group.

29. A polymer according to claim 27 wherein the optionally substituted arylene or heteroarylene repeat unit is an optionally substituted fluorene repeat unit.

30. A polymer according to claim 27 wherein the optionally substituted fluorene repeat unit has formula: 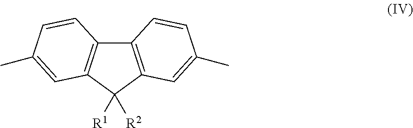
wherein R¹ and R² are independently selected from:
hydrogen;
Ar, wherein Ar is selected from the group consisting of aryl or heteroaryl optionally substituted with one or more substituents selected from halogen; CN; and alkyl wherein one or more non-adjacent C atoms of the alkyl group may be replaced with O, S, N, C═O and —COO and wherein one or more H atoms of the alkyl group may be replaced by a halogen;
alkyl wherein one or more non-adjacent C atoms of the alkyl group may be replaced with O, S, N, C═O and —COO— and wherein one or more H atoms of the alkyl group may be replaced by a halogen or by Ar; and
a crosslinkable group.

31. A polymer according to claim 28 wherein the crosslinkable group comprises a crosslinkable benzocyclobutane.

32. A method of forming an organic light-emitting device comprising the steps of:
forming a hole transport layer by depositing a polymer according to claim 17 over an anode from a solution in a solvent;
evaporating the solvent and crosslinking at least some of the crosslinkable repeat units;
forming a light-emitting layer by depositing a light-emitting material over the hole transport layer from a solution in a solvent; and
depositing a cathode over the light-emitting layer.

33. A polymer comprising an optionally substituted anthracene repeat unit and an optionally substituted repeat unit of formula: 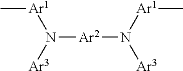
wherein Ar¹ and Ar² each independently represent an optionally substituted aryl or heteroaryl group, and each Ara independently represents an aryl or heteroaryl group.
